(19) United States
(12) Patent Application Publication
(10) Pub. No.: US 2015/0364166 A1
(43) Pub. Date: Dec. 17, 2015

(54) SEMICONDUCTOR DEVICE

(71) Applicant: SK hynix Inc., Gyeonggi-do (KR)

(72) Inventors: Jong-Man IM, Gyeonggi-do (KR); Sung-Soo CHI, Gyeonggi-do (KR)

(21) Appl. No.: 14/527,638

(22) Filed: Oct. 29, 2014

(30) Foreign Application Priority Data
Jun. 16, 2014 (KR) 10-2014-0072959

(51) Int. Cl. G11C 7/12; G11C 11/4091; G11C 11/4094; G11C 7/06

(52) U.S. Cl. CPC G11C 7/12; G11C 7/06; G11C 11/4091; G11C 11/4094

(57) ABSTRACT

A semiconductor device includes: a sense amplification block suitable for sensing and amplifying a data loaded on a pair of data lines based on a pull-up driving voltage supplied through a pull-up power source line and a pull-down driving voltage supplied through a pull-down power source line; and a voltage supply block suitable for supplying a first high voltage as the pull-up driving voltage to the pull-up power source line and a first low voltage as the pull-down driving voltage to the pull-down power source line in a first mode, and supplying the first high voltage as the pull-up driving voltage to the pull-up power source line and a second low voltage having a voltage level lower than a voltage level of the first low voltage as the pull-down driving voltage to the pull-down power source line during an initial period of a second mode which is a subsequent mode of the first mode.

### CROSS-REFERENCE TO RELATED APPLICATIONS

The present application claims priority of Korean Patent Application No. 10-2014-0072959, filed on Jun. 16, 2014, which is incorporated herein by reference in its entirety.

### BACKGROUND

1. Field

Various embodiments of the present invention relate to a semiconductor design technology, and more particularly, to a semiconductor device including a sense amplifier.

2. Description of the Related Art

A dynamic random access memory (DRAM) is a representative volatile memory device. Each of the memory cells of a DRAM includes a cell transistor and a cell capacitor. The cell transistor selects the cell capacitor, and the cell capacitor stores charges corresponding to data.

Since the charges flow in or out of the cell capacitor due to leakage components, the memory cell has to periodically store corresponding data again. The operation that is periodically performed to accurately retain data is referred to as a refresh operation. During the refresh operation, the memory device repeatedly goes between an active mode and a precharge mode at predetermined periods. The refresh operation is performed as follows. In the active mode, the memory cell is selected, and subsequently a bit line sense amplifier is enabled. Thus, the bit line sense amplifier senses and amplifies a data transmitted from the selected memory cell, and then rewrites the data to the memory cell. In the precharge mode, the memory cell is not selected, and the bit line sense amplifier is disabled. Thus, the memory cell retains the stored data.

However, when the leakage components increase, a data retention time of the memory cell, which is a time that the memory cell may retain the data stored in the cell capacitor with reliability after the precharge operation is performed, becomes short. Therefore, a technology for resolving such concerns is in demand.

### SUMMARY

Various embodiments of the present invention are directed to a semiconductor device with improved data retention time of memory cells.

Furthermore, various embodiments of the present invention are directed to a semiconductor device that may improve data retention time of memory cells and improve precharge time of a pair of corresponding data lines in a precharge mode.

Furthermore, various embodiments of the present invention are directed to a semiconductor device with improved time taken for transmitting rewrite data to memory cells, improved data retention time of the memory cells and improved precharge time of a pair of corresponding data lines in a precharge mode.

In accordance with an embodiment of the present invention, a semiconductor device includes: a sense amplification block suitable for sensing and amplifying a data loaded on a pair of data lines based on a pull-up driving voltage supplied through a pull-up power source line and a pull-down driving voltage supplied through a pull-down power source line; and a voltage supply block suitable for supplying a first high voltage as the pull-up driving voltage to the pull-up power source line and a first low voltage as the pull-down driving voltage to the pull-down power source line in a first mode, and supplying the first high voltage as the pull-up driving voltage to the pull-up power source line and a second low voltage having a voltage level lower than a voltage level of the first low voltage as the pull-down driving voltage to the pull-down power source line during an initial period of a second mode which is a subsequent mode of the first mode.

The first mode may include a section in which the data loaded on the data lines is amplified and retained, and the second mode may include a period for precharging the data lines with a predetermined voltage.

The voltage supply block may supply a second high voltage having a voltage level higher than a voltage level of the first high voltage as the pull-up driving voltage during an initial period of the first mode and the first high voltage as the pull-up driving voltage during the remaining period of the first mode.

The voltage supply block may include: a first pull-up driving unit suitable for driving the pull-up power source line with the second high voltage during the initial period of the first mode; a second pull-up driving unit suitable for driving the pull-up power source line with the first high voltage during the remaining period of the first mode; a first pull-down driving unit suitable for driving the pull-down power source line with the first low voltage during the initial period and the remaining period of the first mode; and a second pull-down driving unit suitable for driving the pull-down power source line with the second low voltage during the initial period of the second mode.

The semiconductor device may further include: a first precharge block suitable for precharging the data lines with a predetermined precharge voltage during the remaining period of the second mode; and a second precharge block suitable for precharging the pull-up power source line and the pull-down power source line with the precharge voltage during the remaining period of the second mode.

The precharge voltage may have a voltage level corresponding to a half of the first high voltage.

In accordance with an embodiment of the present invention, a semiconductor device includes: a sense amplification block suitable for sensing and amplifying a data loaded on a pair of data lines based on a pull-up driving voltage supplied through a pull-up power source line and a pull-down driving voltage supplied through a pull-down power source line; and a voltage supply block suitable for supplying a first high voltage as the pull-up driving voltage to the pull-up power source line and a first low voltage as the pull-down driving voltage to the pull-down power source line in a first mode, and supplying a second high voltage having a voltage level higher than a voltage level of the first high voltage as the pull-up driving voltage to the pull-up power source line and a second low voltage having a voltage level lower than a voltage level of the first low voltage as the pull-down driving voltage to the pull-down power source line during an initial period of a second mode which is a subsequent mode of the first mode.

The first mode may include a period in which the data loaded on the data lines is amplified and retained, and the second mode may include a period for precharging the data lines with a predetermined voltage.

The voltage supply block may supply a third high voltage having a voltage level higher than the voltage level of the first high voltage and lower than the voltage level of the second high voltage as the pull-up driving voltage during an initial period of the first mode and the first high voltage as the pull-up driving voltage during the remaining period of the first mode.

The voltage supply block may include: a first pull-up driving unit suitable for driving the pull-up power source line with the third high voltage during the initial period of the first mode; a second pull-up driving unit suitable for driving the pull-up power source line with the first high voltage during the remaining period of the first mode; a third pull-up driving unit suitable for driving the pull-up power source line with the second high voltage during the initial period of the second mode; and a second pull-down driving unit suitable for driving the pull-down power source line with the second low voltage during the initial period of the second mode.

The semiconductor device may further comprising: a first precharge block suitable for precharging the data lines with a predetermined precharge voltage during the remaining period of the second mode; and a second precharge block suitable for precharging the pull-up power source line and the pull-down power source line with the precharge voltage during the remaining period of the second mode.

The precharge voltage may have a voltage level corresponding to a half of the first high voltage.

In accordance with an embodiment of the present invention, a semiconductor device includes: a pair of bit lines including a bit line and a complementary bit line; a memory cell which is coupled with one bit line between the bit line and the complementary bit line; a sense amplification block suitable for sensing and amplifying a data loaded on the bit lines based on a pull-up driving voltage supplied through a pull-up power source line and a pull-down driving voltage supplied through a pull-down power source line; a first pull-up driving block suitable for driving the pull-up power source line with a boosted voltage during an initial period of a precharge mode; a first pull-down driving block suitable for driving the pull-down power source line with a negative voltage during the initial period of the precharge mode; and a first precharge block suitable for precharging the bit lines with a predetermined precharge voltage during the remaining period of the precharge mode.

The semiconductor device may further include: a second pull-up driving unit suitable for driving the pull-up power source line with a power source voltage having a voltage level lower than a voltage level of the boosted voltage during an initial period of an active mode; a third pull-up driving unit suitable for driving the pull-up power source line with an internal voltage having a voltage level lower than a voltage level of the power source voltage during the remaining period of the active mode; and a second pull-down driving unit suitable for driving the pull-down power source line with a ground voltage having a voltage level higher than a voltage level of the negative voltage during the initial period and the remaining period of the active mode.

The precharge voltage may have a voltage level corresponding to a half of the internal voltage.

The internal voltage may include a core volt gel and the precharge voltage includes a bit line precharge voltage.

The semiconductor device may further include: a second precharge block suitable for precharging the pull-up power source line and the pull-down power source line with the precharge voltage during the remaining period of the precharge mode.

### BRIEF DESCRIPTION OF THE DRAWINGS

FIG. 1 is a block diagram illustrating a semiconductor device.

FIG. 2 is a timing diagram for describing an operation of the semiconductor device shown in FIG. 1.

FIG. 3 is a wave form diagram for describing changes in voltage levels of a pair of bit lines according to an operation of the semiconductor device shown in FIG. 1.

FIG. 4 is a block diagram illustrating a semiconductor device in accordance with an embodiment of the present invention.

FIG. 5 is a timing diagram for describing an operation of the semiconductor device shown in FIG. 4.

FIG. 6 is a wave form diagram for describing changes voltage levels of a pair of bit lines according to an operation of the semiconductor device shown in FIG. 4.

### DETAILED DESCRIPTION

Hereafter, various embodiments of the present invention are described below in more detail with reference to the accompanying drawings. The present invention may, however, be embodied in different forms and should not be construed as limited to the embodiments set forth herein. Rather, these embodiments are provided so that this disclosure is thorough and complete, and fully convey the scope of the present invention to those skilled in the art. Throughout the disclosure, reference numerals correspond directly to like parts in the various figures and embodiments of the present invention.

The drawings are not necessarily to scale and in some instances, proportions may have been exaggerated to dearly illustrate features of the embodiments. In this specification, specific terms have been used. The terms are used to describe the present invention, and are not used to qualify the sense or limit the scope of the present invention. It is also noted that in this specification, “and/or” represents that one or more of components arranged before and after “and/or” is included. Furthermore, “connected/coupled” refers to one component not only directly coupling another component but also indirectly coupling another component through an intermediate component. In addition, a singular form may include a plural form as long as it is not specifically mentioned in a sentence. Furthermore, “include/comprise” or “including/comprising” used in the specification represents that one or more components, steps, operations, and elements exists or are added.

A DRAM is described below as an example of a semiconductor device.

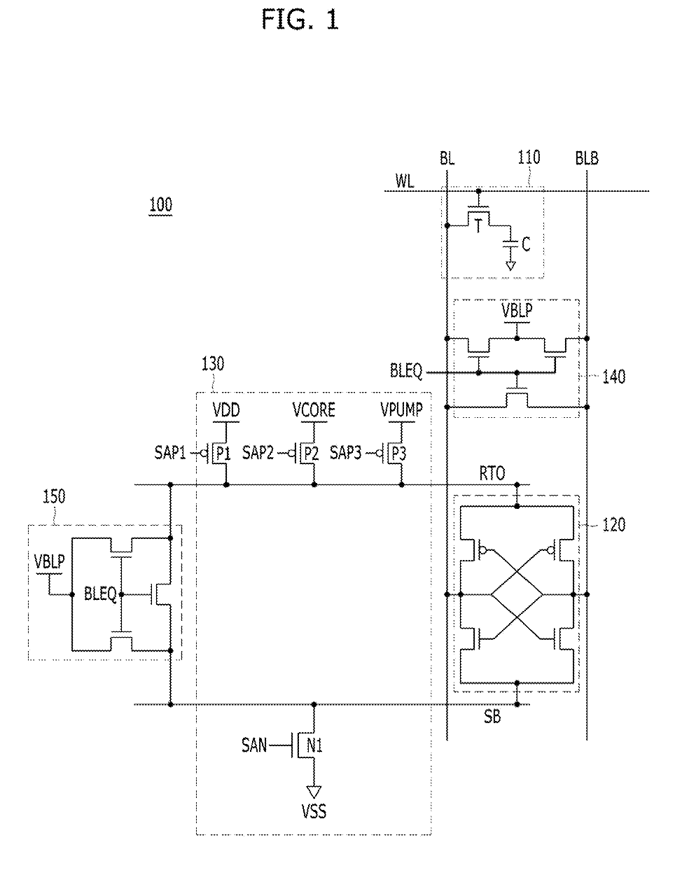

FIG. 1 is a block diagram illustrating a semiconductor device 100.

Referring to FIG. 1, the semiconductor device 100 may include a pair of bit lines BL and BLB, a memory cell 110, a sense amplification block 120, a voltage supply block 130, a first precharge block 140, and a second precharge block 150. The pair of bit lines include a bit line BL and a complementary bit line BLB. The memory cell 110 is coupled with one bit line between the bit line BL and the complementary bit line BLB. The sense amplification block 120 senses and amplifies a data loaded on the bit lines BL and BLB based on a pull-up driving voltage supplied through a pull-up power source line RT0 and a pull-down driving voltage supplied through a pull-down power source line SB. The voltage supply block 130 supplies a power source voltage VDD and a core voltage VCORE as the pull-up driving voltage to the pull-up power source line RT0 and a ground voltage VSS as the pull-down driving voltage to the pull-down power source line SB in an active mode and it supplies a pumping voltage VPUMP as the pull-up driving voltage to the pull-up power source line RT0 and the ground voltage VSS as the pull-down driving voltage to the pull-down power source line SB during an initial period of a precharge mode. The first precharge block 140 precharges the bit lines BL and BLB with a bit line precharge voltage VBLP in the precharge mode. The second precharge block 150 precharges the pull-up power source line RT0 and the pull-down power source line SB with the bit line precharge voltage VBLP in the precharge mode.

Herein, the core voltage VCORE, the bit line precharge voltage VBLP and the pumping voltage VPUMP may be internal voltages, which are internally generated based on the power source voltage VDD supplied from an exterior. For example, the core voltage VCORE may be generated by reducing the power source voltage VDD, and the bit line precharge voltage VBLP may be generated by reducing the core voltage VCORE, for example, VBLP=VCORE/2, and the pumping voltage VPUMP may be generated by boosting the power source voltage VDD. Therefore, the bit line precharge voltage VBLP may have a voltage level, which is lower than a voltage level of the core voltage VCORE, and the core voltage VCORE may have a voltage level, which is lower than a voltage level of the power source voltage VDD, and the pumping voltage VPUMP may have a voltage level, which is higher than the voltage level of the power source voltage VDD.

The memory cell 110 may include a cell capacitor storing a data and a transistor T for controlling charge sharing one bit line between the bit line BL and the complementary bit line BLB and the cell capacitor C. For example, the cell capacitor C is coupled between a ground voltage VSS terminal and a storage node, and the transistor T may include an NMOS transistor having a word line WL coupled to a gate, and a source and a drain are coupled between the storage node and the bit line BL. Although not illustrated in FIG. 1, a memory cell is coupled to the complementary bit line BLB.

The sense amplification block 120 may sense and amplify a data loaded on the bit lines BL and BLB with driving voltages supplied through the pull-up power source line RT0 and the pull-down power source line SB. For example, the sense amplification block 120 may include a cross-coupled latch amplifier.

The voltage supply block 130 may include a first pull-up driving unit P1, a second pull-up driving unit P2, a third pull-up driving unit P3, and a first pull-down driving unit N1. The first pull-up driving unit P1 drives the pull-up power source line RT0 with the power source voltage VDD during an initial period of an active mode based on a first pull-up driving signal SAP1. The second pull-up driving unit P2 drives the pull-up power source line RT0 with the core voltage VCORE during the remaining period of the active mode based on a second pull-up driving signal SAP2. The third pull-up driving unit P3 drives the pull-up power source line RT0 with the pumping voltage VPUMP during an initial period of a precharge mode based on a third pull-up driving signal SAP3. The first pull-down driving unit N1 drives the pull-down power source line SB with the ground voltage VSS during the entire period of the active mode and the initial period of the precharge mode based on a pull-down driving signal SAN.

The first precharge block 140 may precharge the bit lines BL and BLB with the bit line precharge voltage VBLP during the remaining period of the precharge mode based on an equalization signal BLEQ.

The second precharge block 150 may precharge the pull-up power source line RT0 and the pull-down power source line SB with the bit line precharge voltage VBLP during the remaining period of the precharge mode based on the equalization signal BLEQ.

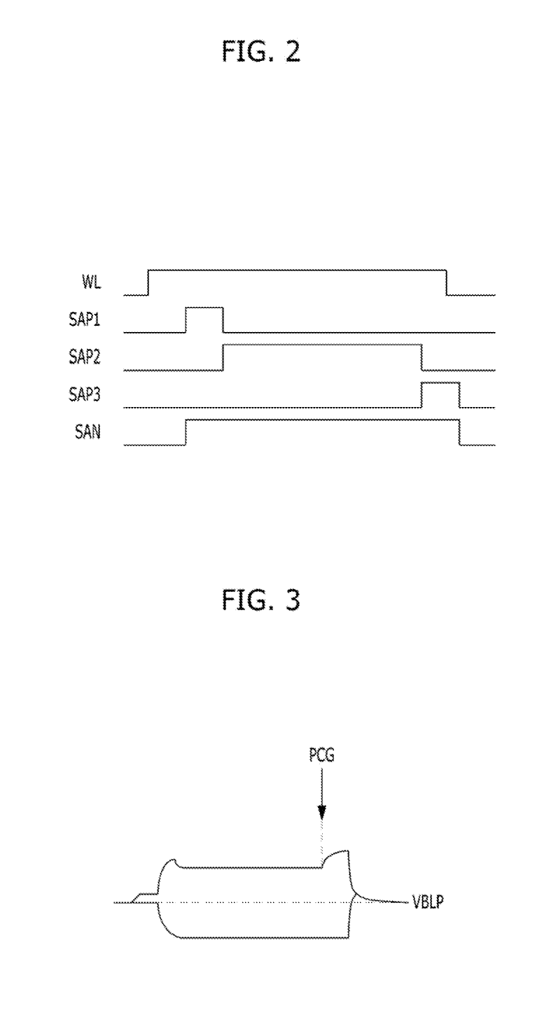

FIG. 2 is a timing diagram for describing an operation of the semiconductor device shown in FIG. 1. FIG. 3 is a wave form diagram for describing changes in voltage levels of the bit lines BL and BLB according to the operation of the semiconductor device shown in FIG. 1.

Referring to FIGS. 2 and 3, the word line WL may be activated to a logic high level during a period corresponding to the active mode and deactivated to a logic low level during a period corresponding to the precharge mode. For example, the word line WL may be activated based on an active command (not shown) and deactivated based on a precharge command PCG.

The first pull-up driving signal SAP1 may be activated during a portion of the initial period of the active mode, and the second pull-up driving signal SAP2 may be activated during the remaining period of the active mode after the first pull-up driving signal SAP1 is deactivated. The third pull-up driving signal SAP3 may be activated during the initial period of the precharge mode after the second pull-up driving signal SAP2 is deactivated, and the pull-down driving signal SAN may be continuously activated during a portion of the initial period of the active mode and the initial period of the precharge mode. For example, the first to third pull-up driving signals SAP1, SAP2 and SAP3 and the pull-down driving signal SAN may be generated by a combination of the active command and the precharge command PCG.

The memory cell 110 has charge sharing between the bit line BL and the cell capacitor C while the cell transistor T is turned on in the active mode. When it is presumed that a data having a logic high level is stored in the cell capacitor C, the bit line BL may increase as high as a predetermined voltage level from a bit line precharge voltage VBLP level. Thus, a predetermined voltage level may occur between the bit line BL and the complementary bit line BLB.

In this condition, the first pull-up driving unit P1 may drive the pull-up power source line RT0 with the power source voltage VDD during a portion of the initial period of the active mode based on the first pull-up driving signal SAP1, and the first pull-down driving unit N1 may drive the pull-down power source line SB with the ground voltage VSS during a portion of the initial period of the active mode based on the pull-down driving signal SAN. Consequently, the sense amplification block 120 may amplify a voltage level of the bit line BL to the power source voltage VDD and a voltage level of the complementary bit line BLB to the ground voltage VSS during a portion of the initial period of the active mode. That is, the sense amplification block 120 may sense and amplify the data loaded on the bit lines BL and BLB based on the power source voltage VDD and the ground voltage VSS. An operation of amplifying a voltage level to a voltage having a higher level, such as, VDD, than a target voltage, such as, VCORE, during an initial period of the sense amplification block 120 which indicates a portion of the initial period of the active mode, is referred to as an over-driving operation.

The second pull-up driving unit P2 may drive the pull-up power source line RT0 with the core voltage VCORE during the remaining period of the active mode based on the second pull-up driving signal SAP2, and the first pull-down driving unit N1 may drive the pull-down power source line SB with the ground voltage VSS during the remaining period of the active mode based on the pull-down driving signal SAN. Consequently, the sense amplification block 120 may retain the voltage level of the bit line BL as the core voltage VCORE and the voltage level of the complementary bit line BLB as the ground voltage VSS during the remaining period of the active mode.

The third pull-up driving unit P3 may drive the pull-up power source line RT0 with the pumping voltage VPUMP during the initial period of the precharge mode based on the third pull-up driving signal SAPS, and the first pull-down driving unit N1 may drive the pull-down power source line SB with the ground voltage VSS during the initial period of the precharge mode based on the pull-down driving signal SAN. Consequently, the sense amplification block 120 may amplify the voltage level of the bit line BL to the pumping voltage VPUMP and retain the voltage level of the complementary bit line BLB as the ground voltage VSS during the initial period of the precharge mode. That is, the sense amplification block 120 may perform the over-driving operation during the initial′ period of the precharge mode.

Subsequently, the first precharge block 140 may precharge the bit lines BL and BLB with the bit line precharge voltage VBLP during the remaining period of the precharge mode, and the second precharge block 150 may precharge the pull-up power source line RT0 and the pull-down power source line SB with the bit line precharge voltage VBLP during the remaining period of the precharge mode.

In accordance with the semiconductor device shown in FIG. 1, since a data having a logic high level corresponding to the pumping voltage VPUMP is rewritten to the cell capacitor C during the initial period of the precharge mode before the memory cell 110 is deactivated, a data retention time may be improved during the remaining period of the precharge mode. Also, although not illustrated in the drawing, a time for rewriting a write data to the memory cell 110 may be improved due to the over-driving operation during the initial period of the precharge mode when a write operation is performed during the remaining period of the active mode.

However, in the semiconductor device 100, it takes a long time for the bit lines BL and BLB to be precharged with the bit line precharge voltage VBLP in the precharge mode as shown in FIG. 3. This is due to the bit lines BL and BLB not accurately being precharged to the bit line precharge voltage VBLP level which is a medium level of the core voltage VCORE and the ground voltage VSS as the voltage level of the bit line BL is amplified to the pumping voltage VPUMP due to the over-driving operation during the initial period of the precharge mode. Therefore, the semiconductor device 100 has a precharge time tRP that may deteriorate, and noise may occur in the bit line precharge voltage VBLP in the precharge mode.

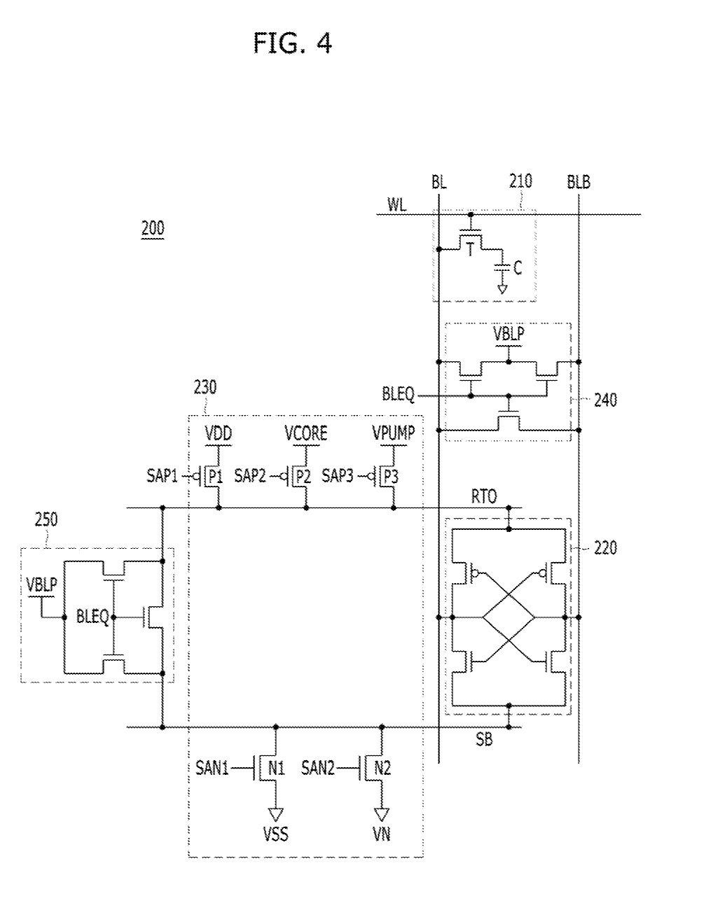

FIG. 4 is a block diagram illustrating a semiconductor device 200 in accordance with an embodiment of the present invention.

Referring to FIG. 4, the semiconductor device 200 may include a pair of bit lines BL and BLB, a memory cell 210, a sense amplification block 220, a voltage supply block 230, a first precharge block 240, and a second precharge block 250.

The bit lines BL and BLB include a bit line BL and a complementary bit line BLB. The memory cell 210 is coupled with one bit line between the bit line BL and the complementary bit line BLB. Although not illustrated in FIG. 4, a memory cell is coupled to the complementary bit line BLB.

The sense amplification block 220 senses and amplifies a data loaded on the bit lines BL and BLB based on a pull-up driving voltage supplied through a pull-up power source line RT0 and a pull-down driving voltage supplied through a pull-down power source line SB. The voltage supply block 230 supplies a power source voltage VDD and a core voltage VCORE as the pull-up driving voltage to the pull-up power source line RT0 and a ground voltage VSS as the pull-down driving voltage to the pull-down power source line SB in an active mode and it supplies a pumping voltage VPUMP as the pull-up driving voltage to the pull-up power source line RT0 and a negative voltage VN as the pull-down driving voltage to the pull-down power source line SB during an initial period of a precharge mode. The first precharge block 240 precharges the bit lines BL and BLB with a bit line precharge voltage VBLP during the remaining period of the precharge mode. The second precharge block 250 precharges the pull-up power source line RT0 and the pull-down power source line SB with the bit line precharge voltage VBLP during the remaining period of the precharge mode.

Herein, the core voltage VCORE, the bit line precharge voltage VBLP, the pumping voltage VPUMP and the negative voltage VN may be internal voltages which are internally generated based on the power source voltage VDD and the ground voltage VSS supplied from an exterior. For example, the core voltage VCORE may be generated by reducing the power source voltage VDD, and the bit line precharge voltage VBLP may be generated by reducing the core voltage VCORE, for example, VBLP=VCORE/2 and the pumping voltage VPUMP may be generated by boosting the power source voltage VDD, and the negative voltage VN may be generated by reducing the ground voltage VSS. Therefore, the bit line precharge voltage VBLP may have a voltage level, which is lower than a voltage level of the core voltage VCORE, and the core voltage VCORE may have a voltage level, which is lower than a voltage level of the power source voltage VDD. The pumping voltage VPUMP may have a voltage level, which is higher than the voltage level of the power source voltage VDD, and the negative voltage VN may have a voltage level, which is lower than a voltage level of the ground voltage VSS.

The memory cell 210 may include a cell capacitor C storing a data and a transistor T for controlling charge sharing one bit line between the bit line BL and the complementary bit line BLB and the cell capacitor C. For example, the cell capacitor C may be coupled between a ground voltage VSS terminal and a storage node, and the transistor T may include an NMS transistor of which a word line WL is coupled with a gate, and a source and a drain are coupled between the storage node and the bit line BL.

The sense amplification block 220 may sense and amplify a data loaded on the bit lines BL and BLB with the driving voltages supplied through the pull-up power source line RT0 and the pull-down power source line SB. For example, the sense amplification block 220 may include a cross-coupled latch amplifier.

The voltage supply block 230 may include pull-up driving circuit units P1, P2 and P3 for driving the pull-up power source line RT0 with different voltages during different periods and pull-down driving circuit units N1 and N2 for driving the pull-down power source line SB with different voltages during different periods.

The pull-up driving circuit units P1, P2 and P3 may be divided into a first pull-up driving unit P1, a second pull-up driving unit P2, and a third pull-up driving unit P3. The first pull-up driving unit P1 drives the pull-up power source line RT0 with the power source voltage VDD during a portion of an initial period of an active mode based on a first pull-up driving signal SAP1. The second pull-up driving unit P2 drives the pull-up power source line RT0 with the core voltage VCORE during the remaining period of the active mode including periods after a portion of the initial period passes among the entire periods of the active mode based on a second pull-up driving signal SAP2. The third pull-up driving unit P3 drives the pull-up power source line RT0 with the pumping voltage VPUMP during an initial period of a precharge mode based on a third pull-up driving signal SAP3. For example, the first pull-up driving unit P1 may include a first. PMOS transistor of which the first pull-up driving signal SAP1 is inputted to a gate, and a source and a drain are coupled between a power source voltage VDD terminal and the pull-up power source line RT0, and the second pull-up driving unit P2 may include a second PMOS transistor of which the second pull-up driving signal SAP2 is inputted to a gate, and a source and a drain are coupled between a core voltage VCORE terminal and the pull-up power source line RT0, and the third pull-up driving unit P3 may include a third PMOS transistor of which the third pull-up driving signal SAPS is inputted to a gate, and a source and a drain are coupled between a pumping voltage VPUMP terminal and the pull-up power source line RT0.

The pull-down driving circuit units N1 and N2 may be divided into a first pull-down driving unit N1 and a second pull-down driving unit N2. The first pull-down driving unit N1 drives the pull-down power source line SB with the ground voltage VSS during a portion of the initial period and the remaining period of the active mode based on a first pull-down driving signal SAN1. The second pull-down driving unit N2 drives the pull-down power source line SB with the negative voltage VN during the initial period of the precharge mode based on a second pull-down driving signal SAN2. For example, the first pull-down driving unit N1 may include a first. NMOS transistor of which the first pull-down driving signal SAN1 is inputted to a gate, and a source and a drain are coupled between a ground voltage VSS terminal and the pull-down power source line SB, and the second pull-down driving unit N2 may include a second NMOS transistor of which the second pull-down driving signal SAN2 is inputted to a gate, and a source and a drain are coupled between the ground voltage VSS terminal and the pull-down power source line SB.

The first precharge block 240 may precharge the bit lines BL and BLB with the bit line precharge voltage VBLP during the remaining period of the precharge mode based on an equalization signal BLEQ, and the second precharge block 250 may precharge the pull-up power source line RT0 and the pull-down power source line SB with the bit line precharge voltage VBLP during the remaining period of the precharge mode based on the equalization signal BLEQ.

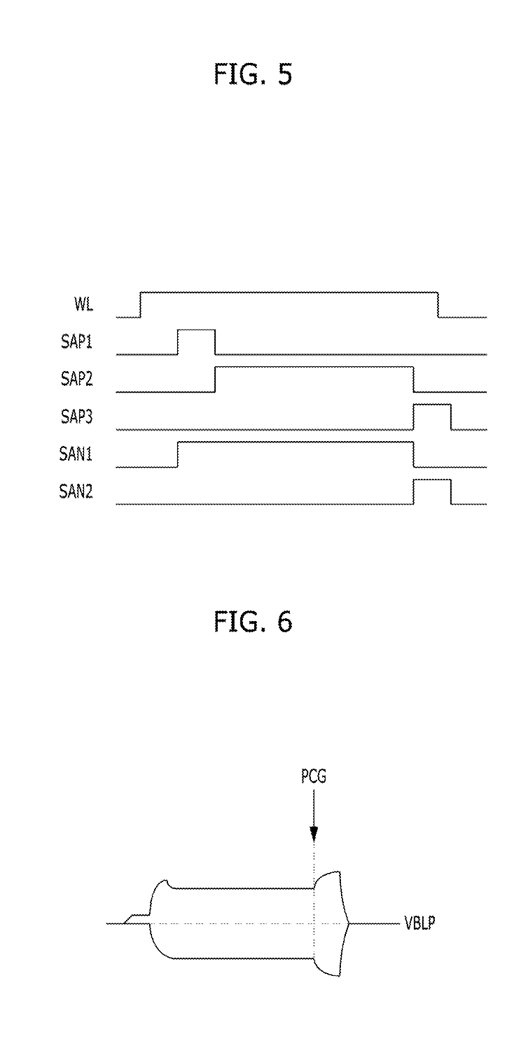

FIG. 5 is a timing diagram for describing an operation of the semiconductor device 200 shown in FIG. 5. FIG. 6 is a wave form diagram for describing changes in voltage levels of the bit lines BL and BLB according to the operation of the semiconductor device 200 shown in FIG. 4.

Referring to FIGS. 5 and 6, the word line WL may be activated to a logic high level during a period corresponding to the active mode and deactivated to a logic low level during a period corresponding to the precharge mode. For example, the word line WL may be activated based on an active command (not shown) and deactivated based on a precharge command PCG.

The first pull-up driving signal SAP1 may be activated during a portion of the initial period of the active mode including periods after a predetermined time passes after the word line WL is activated, and the second pull-up driving signal SAP2 may be activated during the remaining period of the active mode after the first pull-up driving signal SAP1 is deactivated, and the third pull-up driving signal SAP3 may be activated during the initial period of the precharge mode after the second pull-up driving signal SAP2 is deactivated. The first pull-down driving signal SAN1 may be continuously activated during a portion of the initial period and the remaining period of the active mode, the second pull-down driving signal SAN2 may be activated during the initial period of the precharge mode after the first pull-down driving signal SAN1 is deactivated. For example, the first to third pull-up driving signals SAP1, SAP2 and SAP3 and the first and second pull-down driving signals SAN1 and SAN2 may be generated in a combination of the active command and the precharge command PCG.

The memory cell 210 has charge sharing between the bit line BL and the cell capacitor C while the cell transistor T is turned on in the active mode. When it is presumed that a data having a logic high level is stored in the cell capacitor C, the bit line BL may increase as high as a predetermined voltage level from a bit line precharge voltage VBLP level. Thus, a predetermined voltage level may occur between the bit line BL and the complementary bit line BLB.

In this condition, the first pull-up driving unit P1 may drive the pull-up power source line RT0 with the power source voltage VDD during a portion of the initial period of the active mode based on the first pull-up driving signal SAP1, and the first pull-down driving unit N1 may drive the pull-down power source line SB with the ground voltage VSS during a portion of the initial period of the active mode based on the first pull-down driving signal SAN1. Consequently, the sense amplification block 220 may amplify a voltage level of the bit line BL to the power source voltage VDD and a voltage level of the complementary bit line BLB to the ground voltage VSS during a portion of the initial period of the active mode. That is, the sense amplification block 220 may sense and amplify the data loaded on the bit lines BL and BLB based on the power source voltage VDD and the ground voltage VSS. An operation of amplifying a voltage level to a voltage having a higher level, such as, VDD, than a target voltage, such as, VCORE, during an initial period of the sense amplification block 220, which indicates a portion of the initial period of the active mode, is referred to as an over-driving operation.

The second pull-up driving unit P2 may drive the pull-up power source line RT0 with the core voltage VCORE during the remaining period of the active mode based on the second pull-up driving signal SAP2, and the first pull-down driving unit N1 may drive the pull-down power source line SB with the ground voltage VSS during the remaining period of the active mode based on the first pull-down driving signal SAN1. Consequently, the sense amplification block 220 may retain the voltage level of the bit line BL as the core voltage VCORE and the voltage level of the complementary bit line BLB as the ground voltage VSS during the remaining period of the active mode.

The third pull-up driving unit P3 may drive the pull-up power source line RT0 with the pumping voltage VPUMP during the initial period of the precharge mode based on the third pull-up driving signal SAPS, and the second pull-down driving unit N2 may drive the pull-down power source line SB with the negative voltage VN during the initial period of the precharge mode based on the second pull-down driving signal SAN2. Consequently, the sense amplification block 220 may amplify the voltage level of the bit line BL to the pumping voltage VPUMP and the voltage level of the complementary bit line BLB to the negative voltage VN during the initial period of the precharge mode. That is, the sense amplification block 220 may simultaneously perform an under-driving operation and the over-driving operation during the initial period of the precharge mode. The under-driving operation means an operation of amplifying a voltage level to a voltage having a lower level, such as, VN, than a target voltage, such as, VSS.

Subsequently, the first precharge block 240 may precharge the bit lines BL and BLB with the bit line precharge voltage VBLP during the remaining period of the precharge mode, and the second precharge block 250 may precharge the pull-up power source line RT0 and the pull-down power source line SB with the bit line precharge voltage VBLP during the remaining period of the precharge mode.

In accordance with the embodiments of the present invention, a data retention time of a data having a logic low level may be improved during the remaining period of the precharge mode as the under-driving operation is performed during the remaining period of the precharge mode. Also, although not illustrated in the drawing, the time taken for transmitting a write data to the memory cell 210 may be improved due to the under-driving operation during the initial period of the precharge mode when a write operation is performed during the remaining period of the active mode. Furthermore, as shown in FIG. 6, a precharge time tRP is improved, and noise does not occur in the bit line precharge voltage VBLP in the precharge mode since the bit lines BL and BLB may be accurately precharged or equalized to a bit line precharge voltage VBLP level which is a medium level of the core voltage VCORE and the ground voltage VSS as the over-driving operation and the under-driving operation are simultaneously performed during the initial′ period of the precharge mode.

In accordance with the embodiments of the present invention, the performance of a refresh operation may be improved since a refresh period may be improved as a data retention time is improved.

Also, in accordance with the embodiments of the present invention, the performance of a data write may be improved since a time tWR of applying a precharge command may be improved as a time of transmitting a write data is improved.

Furthermore, in accordance with the embodiments of the present invention, the performance of a precharge operation may be improved since noise reflected into a precharge voltage used for a precharge mode may be minimized as a precharge time tRP is improved.

While the present invention has been described with respect to the specific embodiments, it is noted that the embodiments of the present invention are not restrictive but descriptive. Further, it is noted that the present invention may be achieved in various ways through substitution, change, and modification, by those skilled in the art without departing from the scope of the present invention as defined by the following claims.

What is claimed is:

1. A semiconductor device, comprising:
a sense amplification block suitable for sensing and amplifying a data loaded on a pair of data lines based on a pull-up driving voltage supplied through a pull-up power source line and a pull-down driving voltage supplied through a pull-down power source line; and
a voltage supply block suitable for supplying a first high voltage as the pull-up driving voltage to the pull-up power source line and a first low voltage as the pull-down driving voltage to the pull-down power source line in a first mode, and supplying the first high voltage as the pull-up driving voltage to the pull-up power source line and a second low voltage having a voltage level lower than a voltage level of the first low voltage as the pull-down driving voltage, to the pull-down power source line during an initial period of a second mode which is a subsequent mode of the first mode.

2. The semiconductor device of claim 1, wherein the first mode includes a section in which the data loaded on the data lines is amplified and retained, and the second mode includes a period for precharging the data lines with a predetermined voltage.

3. The semiconductor device of claim 1, wherein the voltage supply block supplies a second high voltage having a voltage level higher than a voltage level of the first high voltage as the pull-up driving voltage during an initial period of the first mode and the first high voltage as the pull-up driving voltage during the remaining period of the first mode.

4. The semiconductor device of claim 3, wherein the voltage supply block includes:
a first pull-up driving unit suitable for driving the pull-up power source line with the second high voltage during the initial period of the first mode;
a second pull-up driving unit suitable for driving the pull-up power source line with the first high voltage during the remaining period of the first mode;
a first pull-down driving unit suitable for driving the pull-down power source line with the first low voltage during the initial period and the remaining period of the first mode; and
a second pull-down driving unit suitable for driving the pull-down power source line with the second low voltage during the initial period of the second mode.

5. The semiconductor device of claim 1, further comprising:
a first precharge block suitable for precharging the data lines with a predetermined precharge voltage during the remaining period of the second mode; and
a second precharge block suitable for precharging the pull-up power source line and the pull-down power source line with the precharge voltage during the remaining period of the second mode.

6. The semiconductor device of claim 5, wherein the precharge voltage has a voltage level corresponding to a half of the first high voltage.

7. A semiconductor device, comprising:
a sense amplification block suitable for sensing and amplifying a data loaded on a pair of data lines based on a pull-up driving voltage supplied through a pull-up power source line and a pull-down driving voltage supplied through a pull-down power source line; and
a voltage supply block suitable for supplying a first high voltage as the pull-up driving voltage to the pull-up power source line and a first low voltage as the pull-down driving voltage to the pull-down power source line in a first mode, and supplying a second high voltage having a voltage level higher than a voltage level of the first high voltage as the pull-up driving voltage to the pull-up power source line and a second low voltage having a voltage level lower than a voltage level of the first low voltage as the pull-down driving voltage to the pull-down power source line during an initial period of a second mode which is a subsequent mode of the first mode.

8. The semiconductor device of claim 7, wherein the first mode includes a period in which the data loaded on the data lines is amplified and retained, and the second mode includes a period for precharging the data lines with a predetermined voltage.

9. The semiconductor device of claim 7, wherein the voltage supply block supplies a third high voltage having a voltage level higher than the voltage level of the first high voltage and lower than the voltage level of the second high voltage as the pull-up driving voltage during an initial period of the first mode and the first high voltage as the pull-up driving voltage during the remaining period of the first mode.

10. The semiconductor device of claim 9, wherein the voltage supply block includes:
a first pull-up driving unit suitable for driving the pull-up power source line with the third high voltage during the initial period of the first mode;
a second pull-up driving unit suitable for driving the pull-up power source line with the first high voltage during the remaining period of the first mode;
a third pull-up driving unit suitable for driving the pull-up power source line with the second high voltage during the initial period of the second mode; and
a second pull-down driving unit suitable for driving the pull-down power source line with the second low voltage during the initial period of the second mode.

11. The semiconductor device of claim 7, further comprising:
a first precharge block suitable for precharging the data lines with a predetermined precharge voltage during the remaining period of the second mode; and
a second precharge block suitable for precharging the pull-up power source line and the pull-down power source line with the precharge voltage during the remaining period of the second mode.

12. The semiconductor device of claim 11, wherein the precharge voltage has a voltage level corresponding to a half of the first high voltage.

13. A semiconductor device, comprising:
a pair of bit lines including a bit line and a complementary bit line;
a memory cell which is coupled with one bit line between the bit line and the complementary bit line;
a sense amplification block suitable for sensing and amplifying a data loaded on the bit lines based on a pull-up driving voltage supplied through a pull-up power source line and a pull-down driving voltage supplied through a pull-down power source line;
a first pull-up driving block suitable for driving the pull-up power source line with a boosted voltage during an initial period of a precharge mode;
a first pull-down driving block suitable for driving the pull-down power source line with a negative voltage during the initial period of the precharge mode; and
a first precharge block suitable for precharging the bit lines with a predetermined precharge voltage during the remaining period of the precharge mode.

14. The semiconductor device of claim 13, further comprising:
a second pull-up driving unit suitable for driving the pull-up power source line with a power source voltage having a voltage level lower than a voltage level of the boosted voltage during an initial period of an active mode;
a third pull-up driving unit suitable for driving the pull-up power source line with an internal voltage having a voltage level lower than a voltage level of the power source voltage during the remaining period of the active mode; and
a second pull-down driving unit suitable for driving the pull-down power source line with a ground voltage having a voltage level higher than a voltage level of the negative voltage during the initial period and the remaining period of the active mode.

15. The semiconductor device of claim 14, wherein the precharge voltage has a voltage level corresponding to a half of the internal voltage.

16. The semiconductor device of claim 15, wherein the internal voltage includes a core voltage, and the precharge voltage includes a bit line precharge voltage.

17. The semiconductor device of claim 1, further comprising:
a second precharge block suitable for precharging the pull-up power source line and the pull-down power source line with the precharge voltage during the remaining period of the precharge mode.
